(19) United States
(12) Patent Application Publication
(10) Pub. No.: US 2026/0173554 A1
(43) Pub. Date: Jun. 18, 2026

(54) PACKAGE STRUCTURE

(71) Applicant: CHANG CHUN PLASTICS CO., LTD., Taipei City (TW)

(72) Inventors: ZIH-I CHUANG, Taipei City (TW); YUN-JUNG WU, Taipei City (TW); E-MING HO, Taipei City (TW)

(21) Appl. No.: 19/211,909

(22) Filed: May 19, 2025

(30) Foreign Application Priority Data
Dec. 18, 2024 (CN) 202411867180.3
Dec. 18, 2024 (TW) 113149451

(51) Int. Cl. H10F 39/00

(52) U.S. Cl. CPC H10F 39/804

(57) ABSTRACT

A package structure, comprising a light-transmitting sheet, an annular support layer and a substrate, is provided. The annular support layer is disposed on the lower surface of the light-transmitting sheet and has a top surface facing the light-transmitting sheet, a bottom surface opposite to the top surface, an inner surface and an outer surface opposite to the inner surface. The light-transmitting sheet and the annular support layer are disposed on the substrate, thereby forming an encapsulation space. The annular support layer has a height T in m and a width L_{A} at T/2 from 8 to 400 μm, and 0.05≤T/L_{A}≤25. When the annular support layer is characterized by ultraviolet-visible spectroscopy along a direction perpendicular to the top surface and bottom surfaces of the annular support layer, a resulting spectrum has an absorbance A₃₅₅ at 355 nm, and 0.003<A₃₅₅/T≤0.03.

### CLAIM FOR PRIORITY

This application claims the benefit of China Patent Application No. 202411867180.3 filed on Dec. 18, 2024 and the benefit of Taiwan Patent Application No. 113149451 filed on Dec. 18, 2024, the subject matters of which are incorporated herein in their entirety by reference.

### BACKGROUND OF THE INVENTION

### Field of the Invention

The present application provides a package structure, particularly a package structure having low light transmittance and anti-glare functionality. The package structure of the present application is applied for the packaging of semiconductor devices, particularly the packaging of sensor chips.

### Descriptions of the Related Art

CMOS (Complementary Metal-Oxide-Semiconductor) image sensors are semiconductor devices used to capture digital images. Their advantages in high resolution, high speed, low light, etc., make them widely used in various fields that require image capture, such as smart phones, digital cameras, web cameras, surround view systems, advanced driver assistance systems (ADAS) and other fields.

In general, the package structure of a CMOS image sensor involves a glass plate on a sensor chip via ribs formed by curing, for example, a photosensitive resin layer or an adhesive. The ribs are arranged around the periphery of the sensing area of the sensor chip. However, the light passing through the glass plate may be partially reflected by the ribs, thereby affecting the sensing area and causing glare problems. The glare problem poses a significant safety risks in automotive applications such as surround view systems and advanced driving assistance systems. Therefore, there is an urgent need for a package structure having low light transmittance and anti-glare functionality.

In addition, with the trend of miniaturization of CMOS image sensors, package structures must also be correspondingly miniaturized. As a results, the material used in the package structure are required to support a high aspect ratio, strong adhesion, and high accuracy.

### SUMMARY OF THE INVENTION

Given the aforementioned technical problems, the present application aims to provide a package structure which has low light transmittance and anti-glare functionality, while also meeting the demand of miniaturization.

Therefore, an objective of the present application is to provide a package structure, comprising:
a light-transmitting sheet, having an upper surface and a lower surface;
an annular support layer, disposed on the lower surface of the light-transmitting sheet, and having a top surface facing the light-transmitting sheet, a bottom surface opposite to the top surface, an inner surface, and an outer surface opposite to the inner surface; and
a substrate, wherein,
the light-transmitting sheet and the annular support layer are disposed on the substrate with the bottom surface of the annular support layer, thereby forming an encapsulation space,
the annular support layer has a height T in m along a direction perpendicular to the light-transmitting sheet, with a corresponding width L_{A} at T/2, the width L_{A} ranging from 8 μm to 400 μm, and 0.05≤T/L_{A}≤25, preferably 0.4≤T/L_{A}≤3, and
when the annular support layer is characterized by ultraviolet-visible spectroscopy along a direction perpendicular to the top and bottom surfaces of the annular support layer, a resulting spectrum has an absorbance A₃₅₅ at 355 nm, and 0.003<A₃₅₅/T≤0.03.

In one embodiment of the present application, the annular support layer has a transmittance TT₅₅₀ of not higher than 50% for light with a wavelength of 550 nm, and the transmittance TT₅₅₀ is measured with an incident light direction being perpendicular to the top and bottom surfaces of the annular support layer.

In one embodiment of the present application, the spectrum has at least one point within a wavelength ranging from greater than 450 nm to 780 nm where a first derivative equals 0 and a second derivative is less than 0, and the point each independently has an A_{w1}/T value, wherein w1 represents a corresponding wavelength of the point, A_{w1} represents a corresponding absorbance, and 0.003≤A_{w1}/T.

In one embodiment of the present application, the annular support layer has a width L₁ in m at the bottom surface of the annular support layer and a width L₂ in m at the top surface of the annular support layer, and L₁ is not equal to L₂, wherein the width L₂ can be greater than or lower than the width L₁.

In one embodiment of the present application, the inner surface of the annular support layer is a scattering surface that causes incident light to scatter.

In one embodiment of the present application, the light-transmitting sheet is a glass sheet.

In one embodiment of the present application, the substrate is a silicon-containing substrate.

In one embodiment of the present application, the package structure further comprises a sensor chip, wherein the sensor chip is electrically connected to the substrate and is located within the encapsulation space.

### BRIEF DESCRIPTION OF THE DRAWINGS

FIG. 1 is a cross-sectional schematic diagram of an embodiment of a package structure of the present application.

FIG. 2 is a cross-sectional schematic diagram of an embodiment of a package structure of the present application.

FIG. 3 is a cross-sectional schematic diagram of an embodiment of a package structure of the present application.

### DESCRIPTION OF THE PREFERRED EMBODIMENTS

Hereinafter, some embodiments of the present application will be described in detail. However, the present application may be embodied in various embodiments and should not be limited to the embodiments described in the specification Unless additionally explained, the expressions “a,” “the,” or the like, as recited in the specification and the claims, should include both the singular and plural forms.

Unless additionally explained, in the specification and the claims, when it is stated that an element is “on” another element, it includes the case where the element is directly disposed on the element and also includes the case where there is an intervening element between the two elements.

Unless additionally explained, the expressions “first,” “second,” or the like, as recited in the specification and the claims, are used solely to distinguish the illustrated elements or components without special meanings. These expressions are not used to represent any priority.

The advantage of the present application over prior art particularly lies in that, by controlling the absorbance of the support layer of the package structure to light with specific wavelengths, the support layer has high adhesion and high accuracy (in terms of cross-sectional profiles of patterns), and the package structure is endowed with low light transmittance and anti-glare functionality. Details regarding the package structure of the present application and its applications are provided below.

### 1. PACKAGE STRUCTURE

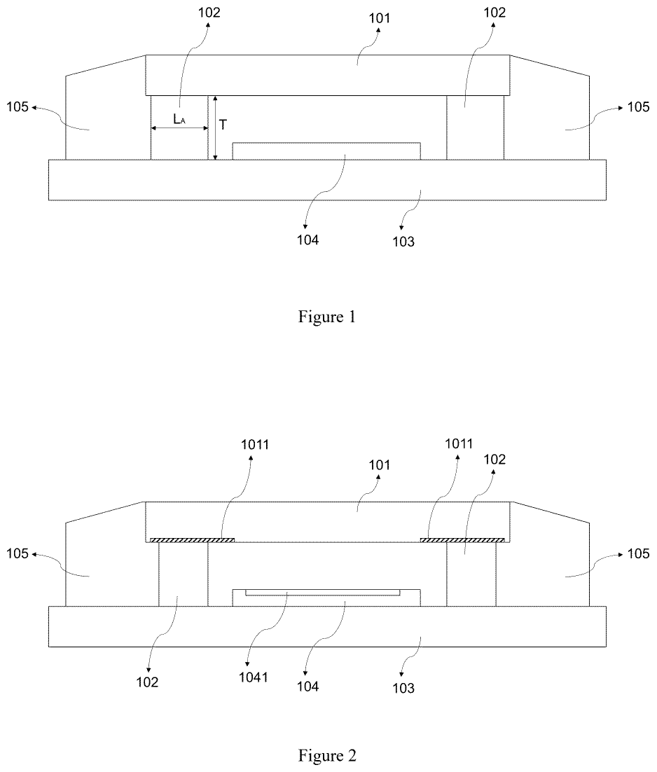

FIG. 1 is a cross-sectional schematic diagram, showing one embodiment of a package structure of the present application. As shown in FIG. 1, the package structure of the present application comprises a light-transmitting sheet 101, an annular support layer 102 and a substrate 103. The annular support layer 102 is disposed on the lower surface of the light-transmitting sheet 101; and the light-transmitting sheet 101 and the annular support layer 102 are disposed on the substrate with the bottom surface of the annular support layer, thereby forming an encapsulation space. A sensor chip 104 which is electrically connected to the substrate is encapsulated within the encapsulation space. Examples of the sensor chip 104 include, but are not limited to, an image sensor chip, more particularly a CMOS image sensor chip.

As shown in FIG. 1, the package structure may further comprise a package body 105 formed on the substrate, in which the sensor chip 104 and the annular support layer 102 both are embedded, thereby protecting the sensor chip 104 from the influence of environmental factors (e.g., dust, moisture, chemicals and mechanical impacts). The material of the package body 105 is not particularly limited and may, for example, be a cured resin; however, the present application is not limited thereto.

### 1.1. Light-Transmitting Sheet

The material of the light-transmitting sheet 101 is not particularly limited, and may be any material that allows light with a wavelength of interest (e.g., visible light) to pass through and reach the sensor chip 104. Examples of the material of the light-transmitting sheet 101 include, but are not limited to, glass, a crystalline inorganic material, and a non-photosensitive resin material. Examples of the non-photosensitive resin material include, but are not limited to, a transparent plastic material. In one embodiment of the present application, the light-transmitting sheet is a glass sheet, for example, a low-alkali glass sheet, an alkali-free glass sheet, a quartz glass sheet, a borosilicate glass sheet. The thickness of the aforementioned glass sheet may be, for example, from 50 m to 2000 km.

The light-transmitting sheet 101 has a lower surface facing the annular support layer 102, and an upper surface opposite to the lower surface. As shown in FIG. 2, in one embodiment of the present application, the lower surface of the light-transmitting sheet further has an annular rough area 1011 whose shape is adapted to the annular support layer, whose setting range does not cover an area of the light-transmitting sheet which is directly above a sensing area 1041 of the sensor chip 104. The annular rough area 1011 can cause light passing through the light-transmitting sheet 101 to scatter, thereby preventing the aforementioned light from being reflected into the sensing area 1041 of the sensor chip, thereby further mitigating glare generated within the package structure. The roughness of the annular rough area 1011 is not further limited as long as it can provide the desired scattering effect.

### 1.2. Annular Support Layer

### 1.2.1. Structural Properties

The annular support layer 102 is disposed on the lower surface of the light-transmitting sheet 101, and has a top surface facing the light-transmitting sheet, a bottom surface opposite to the top surface, an inner surface, and an outer surface opposite to the inner surface, wherein the inner surface faces the encapsulation space. The outer surface of the annular support layer 102 may be roughened or designed with a surface microstructure (e.g., a sawtooth microstructure) to enhance adhesion with the package body 105. The inner surface of the annular support layer 102 may also be roughened or designed with a surface microstructure (such as a sawtooth microstructure) to provide a light-scattering surface function, thereby scattering light irradiated to the inner surface. This scattering prevents the light from being reflected into the sensing area 1041 of the sensor chip 104, thereby further mitigating glare generated within the package structure.

The annular support layer 102 has an annular structure. The “annular” shape may be any shape that is adapted to the object to be encapsulated, and examples thereof include, but are not limited to, a circular ring, an elliptical ring, a rectangular ring, and other polygonal rings other than the rectangular ring.

As shown in FIG. 1, in the package structure of the present application, the annular support layer has a height T in m along a direction perpendicular to the light-transmitting sheet, with a corresponding width L_{A} at T/2. The width L_{A} ranges from 8 μm to 400 μm, and 0.05≤T/L_{A}≤25, preferably 0.4≤T/L_{A}≤3. For example, the width L_{A} can be 8 μm, 10 μm, 20 μm, 50 μm, 100 μm, 110 μm, 120 μm, 130 μm, 140 μm, 150 μm, 160 μm, 170 μm, 180 μm, 190 μm, 200 μm, 210 μm, 220 μm, 230 μm, 240 μm, 250 μm, 260 μm, 270 μm, 280 μm, 290 μm, 300 μm, 310 μm, 320 μm, 330 μm, 340 μm, 350 μm, 360 μm, 370 μm, 380 μm, 390 μm, or 400 μm, or within a range between any two of the values described herein. T/L_{A} can be 0.05, 0.1, 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 4, 5, 6, 7, 8, 9, 10, 11, 12, 13, 14, 15, 16, 17, 18, 19, 20, 21, 22, 23, 24, or 25, or within a range between any two of the values described herein.

The annular support layer may have a uniform or non-uniform thickness along the direction of height T. For example, the annular support layer may have a thickness that increases or decreases along the direction of height T, or the annular support layer may have a thickness that first increases and then decreases or first decreases and then increases along the direction of height T. In one embodiment of the present application, the annular support layer has a width L₁ in m at the bottom surface of the annular support layer and a width L₂ in m at the top surface of the annular support layer, and L₁ is not equal to L₂.

### 1.2.2. Light Absorption Properties

### [A₃₅₅/T]

In the present application, when the annular support layer 102 is characterized by ultraviolet-visible spectroscopy along a direction perpendicular to the top and bottom surfaces of the annular support layer, a resulting spectrum has an absorbance A₃₅₅ at 355 nm, and 0.003<A₃₅₅/T≤0.03. For example, the value of A₃₅₅/T can be 0.0035, 0.004, 0.0045, 0.005, 0.0055, 0.006, 0.0065, 0.007, 0.0075, 0.008, 0.0085, 0.009, 0.0095, 0.01, 0.0105, 0.011, 0.0115, 0.012, 0.0125, 0.013, 0.0135, 0.014, 0.0145, 0.015, 0.0155, 0.016, 0.0165, 0.017, 0.0175, 0.018, 0.0185, 0.019, 0.0195, 0.02, 0.0205, 0.021, 0.0215, 0.022, 0.0225, 0.023, 0.0235, 0.024, 0.0245, 0.025, 0.0255, 0.026, 0.0265, 0.027, 0.0275, 0.028, 0.0285, 0.029, 0.0295, or 0.03, or within a range between any two of the values described herein. When the value of A₃₅₅/T of the annular support layer is within the aforementioned range, it particularly has high adhesion.

### [TT₅₅₀]

In one preferred embodiment of the present application, in addition to satisfying the condition of 0.003<A₃₅₅/T≤0.03, the annular support layer has a transmittance TT₅₅₀ of not higher than 50%, preferably not higher than 36%, for light with a wavelength of 550 nm. For example, the transmittance TT₅₅₀ of the annular support layer for light with a wavelength of 550 nm can be 50%, 45%, 42%, 40%, 38%, 36%, 35%, 34%, 32%, 30%, 28%, 26%, 25%, 24%, 22%, 20%, 18%, 16%, 15%, 14%, 12%, 10%, 8%, 6%, 5%, 4%, 2%, 1%, or within a range between any two of the values mentioned herein. The aforementioned transmittance is measured with an incident light direction that is perpendicular to the top and bottom surfaces of the annular support layer.

### [A_{w1}/T]

In one preferred embodiment of the present application, when the annular support layer is characterized by ultraviolet-visible spectroscopy, in addition to satisfying the condition of 0.003<A₃₅₅/T≤0.03, the resulting spectrum has at least one point within a first wavelength range where a first derivative equals 0 and a second derivative is less than 0; that is, the resulting spectrum within a first wavelength range has at least one absorption peak. The aforementioned point each independently has an A_{w1}/T value, wherein w1 represents a corresponding wavelength of the point, A_{w1} represents a corresponding absorbance and 0.003≤A_{w1}/T. The first wavelength range is from greater than 450 nm to 780 nm, more particularly from greater than 480 nm to 730 nm. The relation between A_{w1} and height T (unit: m) satisfies 0.003≤A_{w1}/T, preferably satisfies 0.003≤A_{w1}/T≤0.08, more preferably satisfies 0.003≤A_{w1}/T≤0.03. For example, the value of A_{w1}/T can be 0.0035, 0.004, 0.0045, 0.005, 0.0055, 0.006, 0.0065, 0.007, 0.0075, 0.008, 0.0085, 0.009, 0.0095, 0.01, 0.0105, 0.011, 0.0115, 0.012, 0.0125, 0.013, 0.0135, 0.014, 0.0145, 0.015, 0.0155, 0.016, 0.0165, 0.017, 0.0175, 0.018, 0.0185, 0.019, 0.0195, 0.02, 0.0205, 0.021, 0.0215, 0.022, 0.0225, 0.023, 0.0235, 0.024, 0.0245, 0.025, 0.0255, 0.026, 0.0265, 0.027, 0.0275, 0.028, 0.0285, 0.029, 0.0295, or 0.03, or within a range between any two of the values described herein.

Within the above preferred range, both low light transmittance and anti-glare effects can be achieved while minimizing the influence on the adhesion of the annular support layer.

### [A₄₅₀/T]

In one preferred embodiment of the present application, when the annular support layer is characterized by ultraviolet-visible spectroscopy, in addition to satisfying the conditions of 0.003<A₃₅₅/T≤0.03 and 0.003≤A_{w1}/T, there is no light absorption, substantially no light absorption, or only a small amount of light absorption at 450 nm. Specifically, when the annular support layer is characterized by ultraviolet-visible spectroscopy, the resulting spectrum has an absorbance A₄₅₀ at 450 nm, and the relation between A₄₅₀ and height T (unit: m) satisfies 0≤A₄₅₀/T≤0.0035, preferably satisfies 0≤A₄₅₀/T≤0.0025. For example, A₄₅₀/T can be 0, 0.0005, 0.001, 0.0015, 0.002, or 0.0025, or within a range between any two of the values described herein. In the above preferred range, the annular support layer can have better adhesion and pattern accuracy.

### [A_{w2}/T]

In one preferred embodiment of the present application, when the annular support layer is characterized by ultraviolet-visible spectroscopy, in addition to satisfying the condition of 0.003<A₃₅₅/T≤0.03, the spectrum has the aforementioned technical feature of 0.003≤A_{w1}/T within the first wavelength range of greater than 480 nm to 730 nm and has no light absorption, substantially no light absorption, or only a small amount of light absorption within the second wavelength range. The second wavelength range is from 440 nm to 470 nm. Specifically, when the annular support layer is characterized by ultraviolet-visible spectroscopy, an absorbance of the spectrum at each wavelength within the second wavelength range is independently denoted as A_{w2}, and satisfies the condition of 0≤A_{w2}/T≤0.0035, wherein w2 represents a wavelength of corresponding absorbance. For example, A_{w2}/T can be independently 0, 0.0005, 0.001, 0.0015, 0.002, 0.0025, or 0.003, or within a range between any two of the values described herein. In the above preferred range, the annular support layer can have better adhesion and pattern accuracy.

In the present application, the aforementioned ultraviolet-visible spectroscopy is measured using a ultraviolet-visible spectrophotometer under the following conditions: the annular support layer is placed in a manner such that the top and bottom surfaces thereof are perpendicular to a direction of incident light, that is, the incident light travels along a direction perpendicular to the top and bottom surfaces of the annular support layer; a diffraction grating is configured as an optical splitter; testing temperature is 25° C.; testing pressure is 1 atm; an analysis mode is absorbance; a range of scanned wavelength is from 190 nm to 1100 nm; a blank sample is air; scan velocity is 2200 nm/min; a switch wavelength at which a light source is switched from a deuterium lamp to a tungsten lamp is 340.8 nm; a sampling interval is 0.2 nm; and a slit width is 2.0 nm. Under the aforementioned testing conditions, an annular support layer sample used for analysis is obtained by cutting an annular support layer into a size of 5 cm×3 cm at any position along the transverse direction (TD) and the machine direction (MD). The annular support layer must be placed in a manner such that the top and bottom surfaces thereof are perpendicular to a direction of incident light in order to correctly measure the absorbance of the annular support layer. The wavelength of the tungsten lamp used as the incident light source is 340.8 nm. In addition, the “sampling interval” refers to that, in the scanned wavelength ranging from 190 nm to 1100 nm, a data point is taken every 0.2 nm, and the obtained value is recorded.

The light absorption properties of the annular support layer can be adjusted by adjusting the composition or process conditions. For example, in the case of preparing the annular support layer with a photosensitive resin film as illustrated in the following Examples, the composition of the photosensitive resin film can be adjusted by selecting the type and content of additives, or adjusting the drying conditions of the photosensitive resin film to accordingly adjust the light absorption properties of the annular support layer. The additives include, but not limited to, photopolymerization initiators, light absorbers, dyes, or the like. Persons having ordinary skill in the art would be able to prepare a package structure of the present application having an annular support layer with the aforementioned light absorption properties by referring to the specification of the present application, particularly relying on the specific illustrations in the Examples.

### 1.2.3. Composition of Annular Support Layer

With the premise that A₃₅₅/T satisfies the aforementioned range, the composition of the annular support layer can be adjusted as needed. In one embodiment of the present application, the annular support layer is formed after a photosensitive resin composition is subjected to exposure followed by development, wherein the photosensitive resin composition is an epoxy resin-based photosensitive resin composition, which contains an epoxy resin and optionally contains an ethylenically unsaturated compound, a photopolymerization initiator, and other additives as needed.

### [Epoxy Resin]

Examples of the epoxy resin include, but are not limited to, a bisphenol A epoxy resin, a bisphenol F epoxy resin, a bisphenol S epoxy resin, a bisphenol A novolac epoxy resin, a novolac epoxy resin, an alkyl novolac epoxy resin, a phenol novolac epoxy resin, a cresol novolac epoxy resin, a cycloaliphatic-based epoxy resin, a biphenyl-based epoxy resin, an aralkyl-based epoxy resin, a naphthalene ring-based epoxy resin, a naphthol-based epoxy resin, a biphenyl aralkyl-based epoxy resin, a fluorene-based epoxy resin, an xanthene-based epoxy resin, a dicyclopentadiene-based epoxy resin, a triglycidyl polyisocyanate, and an oxygen heterocycle-based epoxy resin. Each of the aforementioned epoxy resins can be used alone or in combination. In one embodiment of the present application, a bisphenol A epoxy resin, a bisphenol A novolac epoxy resin, a phenol novolac epoxy resin, a cresol novolac epoxy resin, an aliphatic-based epoxy resin, or an oxetane epoxy resin is used.

In the aforementioned photosensitive resin composition, based on the total weight of the photosensitive resin composition, the amount of the epoxy resin can be 50 wt % to 99 wt %, specifically, 55 wt % to 98 wt %, more specifically, 60 wt % to 95 wt %. For example, based on the total weight of the photosensitive resin composition, the amount of the epoxy resin can be 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, 95 wt %, 96 wt %, 97 wt %, 98 wt %, or 99 wt %, or within a range between any two of the values described herein.

### [Ethylenically Unsaturated Compound]

The ethylenically unsaturated compound refers to a compound with at least one reactive ethylene functional group, for example, a bifunctional compound with two reactive ethylene functional groups. Examples of the ethylenically unsaturated compound include, but are not limited to, ethoxylated trimethylolpropane triacrylate, ethoxylated bisphenol-A diacrylate, ethoxylated bisphenol-A dimethacrylate, tripropylene glycol diacrylate, 1,6-hexanediol diacrylate, polypropylene glycol diacrylate, tris((meth)acryloxyisocyanate) hexamethylene isocyanurate, ethoxylated urethane di(meth)acrylate, propoxylated urethane di(meth)acrylate, ethoxylated/propoxylated urethane di(meth)acrylate, ethoxylated tris(methacryloxyisocyanate) hexamethylene isocyanurate, acrylated tris(methacryloxyisocyanate) hexamethylene isocyanurate, and ethoxylated/propoxylated tris(methacryloxyisocyanate) hexamethylene isocyanurate. Each of the aforementioned ethylenically unsaturated compounds can be used alone or in combination. In one embodiment of the present application, ethoxylated trimethylolpropane triacrylate is used.

In the aforementioned photosensitive resin composition, based on the total weight of the photosensitive resin composition, the amount of the ethylenically unsaturated compound can be 0 wt % to 70 wt %. For example, based on the total weight of the photosensitive resin composition, the amount of the ethylenically unsaturated compound can be 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, or 70 wt %, or within a range between any two of the values described herein.

### [Photopolymerization Initiator]

Examples of the photopolymerization initiator include, but are not limited to, imidazole-based compounds, ketone-based compounds, quinone-based compounds, benzoin-based or benzoin ether-based compounds, polyhalogenated compounds, triazine-based compounds, organic peroxide compounds, and onium salt compounds. The aforementioned photopolymerization initiators can be used alone or in combination. In one embodiment of the present application, the onium salt compounds are used. Examples of the aforementioned onium salt compounds include, but are not limited to, diaryliodonium salts and triarylsulfonium salts obtained from diphenyliodonium, 4,4′-dichlorodiphenyliodonium, 4,4′-dimethoxydiphenyliodonium, 4,4′-di-tert-butyldiphenyliodonium, 4-methyl-4′-isopropyldiphenyliodonium, or 3,3′-dinitrodiphenyl iodonium in combination with chloride, bromide, tetrafluoroborate, hexafluorophosphate, hexafluoroarsenate, hexafluoroantimonate, and tetrakis(pentafluorophenyl)borate, or trifluoromethanesulfonic acid.

In the aforementioned photosensitive resin composition, the amount of the photopolymerization initiator based on the total weight of the photosensitive resin composition can be 0.5 wt % to 10 wt %, more specifically 1 wt % to 5 wt %. For example, the amount of the photopolymerization initiator based on the total weight of the photosensitive resin composition can be 0.5 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, or 10 wt %, or within a range between any two of the values described herein.

### [Additives]

With the premise that A₃₅₅/T satisfies the aforementioned range, the photosensitive resin composition can further comprise additives in order to specifically improve the properties of the annular support layer. Examples of the additives include, but are not limited to, light absorbers, dyes, pigments, radical inhibitors, surfactants, tougheners, and plasticizers. Each of the aforementioned additives can be used alone or in combination. In one embodiment of the present application, the photosensitive resin composition can further comprise silane coupling agents, light absorbers and dyes.

In the photosensitive resin composition, the amount of the additives based on the total weight of the photosensitive resin composition preferably is less than 20 wt %. For example, the amount of the additives based on the total weight of the photosensitive resin composition can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, or 19 wt %, or within a range between any two of the values described herein.

### 1.3. Substrate

There is no particular limitation on the type of substrate 103, which can be any substrate known in the packaging field. In one embodiment of the present application, the substrate 103 is a silicon-containing substrate electrically connected to the sensor chip 104, and specifically may be a silicon wafer, a silicon carbide wafer, or a glass substrate.

### 1.4. Optional Elements

In addition to the light-transmitting sheet, the annular support layer and the substrate, the package structure of the present application may optionally further comprise other elements to specifically improve the properties of the package structure or to impart specific functions.

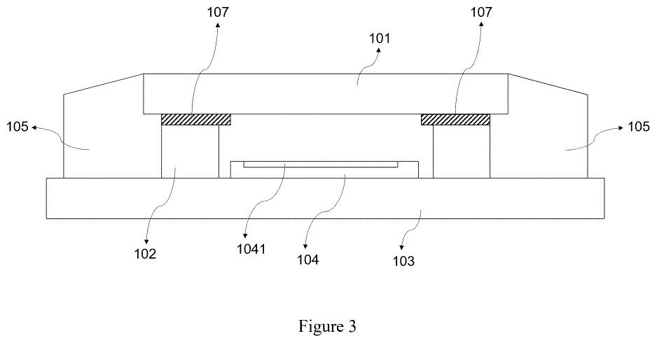

As shown in FIG. 3, in one embodiment of the present application, the package structure further comprises an annular shielding layer 107 disposed between the light-transmitting sheet 101 and the annular support layer 102, and the setting range of the annular shielding layer 107 does not cover an area of the light-transmitting sheet which is directly above the sensing area 1041 of the sensor chip 104. The annular shielding layer 107 can at least partially shield light entering the sensing area 1041 of the sensor chip through the light-transmitting sheet, thereby further mitigating glare generated within the package structure.

### 2. PREPARATION OF PACKAGE STRUCTURE

The preparation method of the package structure of the present invention is not particularly limited. Persons having ordinary skill in the art can implement the preparation of the package structure based on the disclosure of the present specification, especially the specific embodiments of the following Examples. In the following Examples, the package structure is obtained by placing a photosensitive resin film of a selected composition on a light-transmitting sheet, curing the photosensitive resin film to form an annular support layer through exposure and development processes, and then placing the light-transmitting sheet and the annular support layer on a substrate with the bottom surface of the annular support layer. The specific preparation method is shown in the following Examples.

### 3. EXAMPLES

### 3.1. Testing Methods

The present application is further illustrated by the following specific embodiments, wherein the testing instruments and methods used are as follows:

### [Height of Annular Support Layer]

An annular support layer is cut into a size of 5 cm×3 cm to serve as samples. The annular support layer is placed on a base (MS-11C base) of a film thickness meter (Model: Nikon Digimicro MFC-101+MS-11C, purchased from Nikon), and an MFC-101 meter is used to conduct measurement under a pressure of 140 gf. The thickness of the annular support layer at 10 different points is measured and averaged. The obtained averaged value is served as the height T of the annular support layer.

[Width and cross-sectional shape of annular support layer]

A glass cutter is used to cut an annular support layer together with a light-transmitting sheet at an outer edge of a linear space, and the cross-sectional profile of the annular support layer is observed with a scanning electron microscope, wherein test pieces are tilted 75° and a magnification of 200 times is used. A cross-section of the annular support layer is randomly selected and a width L_{A} corresponding to the half-height (i.e., T/2) of the annular support layer is measured.

In addition, a width L₁ at the bottom surface of the annular support layer is obtained as follows: measuring the width of the annular support layer where the thickness is 1/25, 2/25, 3/25, 4/25 and 5/25 of the total thickness of the annular support layer starting from the lower edge of the annular support layer (the side away from the low-alkali glass), and averaging the width values measured at these five locations to obtain a value as the width L₁ at the bottom surface of the annular support layer. Similarly, a width L₂ at the top surface of the annular support layer is obtained as follows: measuring the width of the annular support layer where the thickness is 1/25, 2/25, 3/25, 4/25 and 5/25 of the total thickness of the annular support layer starting from the upper edge of the annular support layer (the side contacting the low-alkali glass), and averaging the width values measured at these five locations to obtain a value as the width L₂ at the top surface of the annular support layer. If the value of “|(L₂−L₁)|/T” is less than 0.04, it is recorded as “∘”, which means the cross-sectional shape of the annular support layer is good; if the value of “|(L₂−L₁)|/T” is 0.04 or higher, it is recorded as “x”, which means the cross-sectional shape of the annular support layer is poor. “|(L₂−L₁)|” in the formula means the absolute value thereof is taken.

### [Footing Length of Annular Support Layer]

A glass cutter is used to cut an annular support layer together with a light-transmitting sheet (a low-alkali glass) at an outer edge of a linear space, and a cross-sectional shape of the annular support layer is observed with a scanning electron microscope, wherein test pieces are tilted 75° and a magnification of 5000 times is used. A footing length is obtained by randomly selecting a cross-section of the annular support layer and selecting a side in which the bottom thereof protruding more toward the linear space to conduct the calculation of the footing length.

Specifically, the footing length is obtained by the following calculation: taking the position of a lateral wall of the annular support layer at which the thickness is ⅕ of the total thickness of the annular support layer starting from the top surface of the annular support layer as a reference point, extending a baseline perpendicular to the low-alkali glass surface from the reference point to the low-alkali glass, and measuring a length from the intersection point of the baseline and the low-alkali glass surface to the intersection point of the lateral wall of the annular support layer and the low-alkali glass surface as a footing length.

### [Absorbance of Annular Support Layer]

An annular support layer is cut into a size of 5 cm×3 cm to serve as samples. The annular support layer is subjected to absorbance measurement using an ultraviolet-visible spectrophotometer (model: Shimadzu UV-1601, purchased from Shimadzu) in the following manner. The annular support layer is placed using a fixture, with its top and bottom surfaces perpendicular to a direction of incident light, and then analyzed to obtain an absorbance spectrum under the following conditions: a diffraction grating is configured as an optical splitter; testing temperature is 25° C.; testing pressure is 1 atm; an analysis mode is absorbance; a range of scanned wavelength is from 190 nm to 1100 nm; a blank sample is air; a scanning speed is 2200 nm/min; a switch wavelength at which a light source is switched from a deuterium lamp to a tungsten lamp is 340.8 nm; a sampling interval is 0.2 nm; a slit width is 2.0 nm; and a Shimadzu UV Probe V1.11 software is used.

### [Light Transmittance of Annular Support Layer]

An annular support layer is cut into a size of 5 cm×3 cm to serve as samples. A light transmittance of the annular support layer is determined using an ultraviolet-visible spectrophotometer (model: Shimadzu UV-1601, purchased from Shimadzu) in the following manner. The annular support layer is placed on an analysis stage by a fixture, with its top and bottom surfaces perpendicular to a direction of an incident light source, and then a light transmittance at wavelength of 550 nm (TT₅₅₀) is measured under the following conditions: an analysis mode is transmittance; a range of scanned wavelength is from 190 nm to 1100 nm; air serves as a blank sample; a scanning speed is 2200 nm/min; a switch wavelength at which a light source is switched from a deuterium lamp to a tungsten lamp is 340.8 nm; and a sampling interval is 0.2 nm.

### [Silicon Adhesion Testing]

An annular support layer together with a low-alkali glass is cut into a size of 1.73 mm×1.73 mm to serve as samples. A bare Si substrate of 3 mm² is placed on a side of the annular support layer that is not in contact with the low-alkali glass, and a pressure of 3 kgf/cm² is applied at 130° C. to perform bonding. Afterwards, a tensile testing machine is used to determine a force required to tear off the bare Si substrate. In the test, the direction of the force application is parallel to the interface of the bare Si substrate and the annular support layer. The force acts directly on the bare Si substrate, and a specific force application point is located at a middle height of a lateral wall of the bare Si substrate. The unit of adhesion is kgf/3 mm².

### 3.2. Information of Raw Materials

The information about the raw materials used in the following Examples and Comparative Examples is shown in Table 1 below.

TABLE 1

| Raw materials | Description |
|---|---|
| BNE200 | Epoxy resin, purchased from Chang Chun Plastics Co., Ltd. |
| BE507 | Epoxy resin, purchased from Chang Chun Plastics Co., Ltd. |
| PNE177 | Epoxy resin, purchased from Chang Chun Plastics Co., Ltd. |
| BNE220 | Epoxy resin, purchased from Chang Chun Plastics Co., Ltd. |
| CNE200ELA | Epoxy resin, purchased from Chang Chun Plastics Co., Ltd. |
| Celloxide 2021P | Epoxy resin, purchased from Daicel |
| TCM201 | Epoxy resin, purchased from Tronly |
| 3EO TMPTA | Ethylenically unsaturated compound, ethoxylated trimethylolpropane |
| | triacrylate |
| Acetone | Solvent |
| Triphenylsulfonium | Photopolymerization initiator |
| hexafluoroantimonate | |
| Triphenylsulfonium | Photopolymerization initiator |
| tetrakis(pentafluorophenyl) | |
| borate | |
| Diphenyliodonium | Photopolymerization initiator |
| tetrakis(pentafluorophenyl) | |
| borate | |
| Triarylsulfonium | Photopolymerization initiator |
| tetrakis(pentafluorophenyl) | |
| borate | |
| SI-45 | Photopolymerization initiator, purchased from Sanshin Chemical |
| KBE-403 | Silane coupling agent, CAS number: 2602-34-8 |
| Solvent Blue | Dye, CAS number: 12226-78-7 |
| Oil Blue | Dye, CAS number: 1325-86-6 |
| Solvent Yellow | Dye, CAS number: 176023-34-0 |
| Reactive Yellow | Dye, CAS number: 12226-48-1 |
| Solvent Black | Dye, CAS number: 1333-86-4 |
| Tetrahydrofuran | Solvent |

### 3.3. Examples 1 to 7 and Comparative Examples 1 and 2

### 3.3.1. Preparation of Photosensitive Resin Film

### Example 1

The following components were mixed and stirred for 5 hours to be evenly mixed, thereby obtaining a resin composition of Example 1: 90 parts by weight of BNE200 epoxy resin, 10 parts by weight of BE507 epoxy resin, 25 parts by weight of acetone, 2 parts by weight of triphenylsulfonium hexafluoroantimonate, 5 parts by weight of KBE-403 silane coupling agent, 0.2 part by weight of Solvent Blue, and 12 parts by weight of tetrahydrofuran.

The resin composition of Example 1 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 1. The conditions of conducting coating and drying are as follows: a coated thickness is 160 m, a drying temperature of 100° C. is applied, a drying duration of 20 minutes is used, and a thickness after drying is 120 m.

### Example 2

The following components were mixed and stirred for 5 hours to be evenly mixed, thereby obtaining a resin composition of Example 2: 20 parts by weight of BNE200 epoxy resin, 60 parts by weight of BE507 epoxy resin, 20 parts by weight of CNE200ELA epoxy resin, 30 parts by weight of acetone, 1.8 parts by weight of triphenylsulfonium tetrakis(pentafluorophenyl)borate, 5 parts by weight of KBE-403 silane coupling agent, 1.2 parts by weight of Oil Blue, and 12 parts by weight of tetrahydrofuran.

The resin composition of Example 2 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 2. The conditions of conducting coating and drying are as follows: a coated thickness is 25 m, a drying temperature of 100° C. is applied, a drying duration of 15 minutes is used, and a thickness after drying is 20 m.

### Example 3

The following components were mixed and stirred for 5 hours to be evenly mixed, thereby obtaining a resin composition of Example 3: 30 parts by weight of BNE200 epoxy resin, 20 parts by weight of BE507 epoxy resin, 50 parts by weight of PNE177 epoxy resin, 35 parts by weight of acetone, 4 parts by weight of triphenylsulfonium tetrakis(pentafluorophenyl)borate, 5 parts by weight of KBE-403 silane coupling agent, 0.5 part by weight of Solvent Blue, and 12 parts by weight of tetrahydrofuran.

The resin composition of Example 3 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 3. The conditions of conducting coating and drying are as follows: a coated thickness is 85 m, a drying temperature of 90° C. is applied, a drying duration of 19 minutes is used, and a thickness after drying is 60 km.

### Example 4

The following components were mixed and stirred for 5 hours to be evenly mixed, thereby obtaining a resin composition of Example 4: 75 parts by weight of BNE200 epoxy resin, 10 parts by weight of BE507 epoxy resin, 5 parts by weight of BNE220 epoxy resin, 10 parts by weight of 3EO TMPTA (ethylenically unsaturated compound), 25 parts by weight of acetone, 4 parts by weight of triarylsulfonium tetrakis(pentafluorophenyl)borate, 5 parts by weight of KBE-403 silane coupling agent, 0.5 part by weight of Oil Blue, and 15 parts by weight of tetrahydrofuran.

The resin composition of Example 4 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 4. The conditions of conducting coating and drying are as follows: a coated thickness is 275 m, a drying temperature of 95° C. is applied, a drying duration of 30 minutes is used, and a thickness after drying is 200 km.

### Example 5

The following components were mixed and stirred for 5 hours to be evenly mixed, thereby obtaining a resin composition of Example 5: 20 parts by weight of BNE200 epoxy resin, 20 parts by weight of BE507 epoxy resin, 20 parts by weight of PNE177 epoxy resin, 20 parts by weight of BNE220 epoxy resin, 10 parts by weight of Celloxide 2021P epoxy resin, 10 parts by weight of TCM201 epoxy resin, 25 parts by weight of acetone, 2 parts by weight of triphenylsulfonium hexafluoroantimonate, 5 parts by weight of KBE-403 silane coupling agent, 0.2 part by weight of Solvent Blue, and 12 parts by weight of tetrahydrofuran.

The resin composition of Example 5 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 5. The conditions of conducting coating and drying are as follows: a coated thickness is 130 m, a drying temperature of 100° C. is applied, a drying duration of 20 minutes is used, and a thickness after drying is 100 m.

### Example 6

The following components were mixed and stirred for 5 hours to be evenly mixed, thereby obtaining a resin composition of Example 6: 50 parts by weight of BNE200 epoxy resin, 40 parts by weight of BE507 epoxy resin, 10 parts by weight of BNE220 epoxy resin, 25 parts by weight of acetone, 1.5 parts by weight of triphenylsulfonium hexafluoroantimonate, 0.5 part by weight of triarylsulfonium tetrakis(pentafluorophenyl)borate, 4 parts by weight of KBE-403 silane coupling agent, 0.3 part by weight of Solvent Blue, 0.05 part by weight of Solvent Yellow, and 12 parts by weight of tetrahydrofuran.

The resin composition of Example 6 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 6. The conditions of conducting coating and drying are as follows: a coated thickness is 130 m, a drying temperature of 90° C. is applied, a drying duration of 25 minutes is used, and a thickness after drying is 100 m.

### Example 7

The following components were mixed and stirred for 5 hours to be evenly mixed, thereby obtaining a resin composition of Example 7: 20 parts by weight of BNE200 epoxy resin, 60 parts by weight of BE507 epoxy resin, 20 parts by weight of PNE177 epoxy resin, 25 parts by weight of acetone, 2 parts by weight of triphenylsulfonium hexafluoroantimonate, 5 parts by weight of KBE-403 silane coupling agent, 0.2 part by weight of Solvent Blue, and 12 parts by weight of tetrahydrofuran.

The resin composition of Example 7 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 7. The conditions of conducting coating and drying are as follows: a coated thickness is 130 m, a drying temperature of 100° C. is applied, a drying duration of 20 minutes is used, and a thickness after drying is 100 m.

### Comparative Example 1

The following components were mixed and stirred for 5 hours to be evenly mixed, thereby obtaining a resin composition of Comparative Example 1: 100 parts by weight of Celloxide 2021P epoxy resin, 25 parts by weight of acetone, 0.3 part by weight of triphenylsulfonium hexafluoroantimonate, 2 parts by weight of SI-45, 5 parts by weight of KBE-403 silane coupling agent, 0.3 part by weight of Solvent Blue, and 12 parts by weight of tetrahydrofuran.

The resin composition of Comparative Example 1 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 1. The conditions of conducting coating and drying are as follows: a coated thickness is 130 m, a drying temperature of 100° C. is applied, a drying duration of 20 minutes is used, and a thickness after drying is 100 m.

### Comparative Example 2

The following components were mixed and stirred for 5 hours to be evenly mixed, thereby obtaining a resin composition of Comparative Example 2: 90 parts by weight of BNE220 epoxy resin, 10 parts by weight of TCM201 epoxy resin, 25 parts by weight of acetone, 1 part by weight of triphenylsulfonium tetrakis(pentafluorophenyl)borate, 4 parts by weight of triarylsulfonium tetrakis(pentafluorophenyl)borate, 5 parts by weight of KBE-403 silane coupling agent, and 12 parts by weight of tetrahydrofuran.

The resin composition of Comparative Example 2 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 2. The conditions of conducting coating and drying are as follows: a coated thickness is 85 m, a drying temperature of 90° C. is applied, a drying duration of 19 minutes is used, and a thickness after drying is 60 m.

### 3.3.2. Preparation of Annular Support Layer and Package Structure

A low-alkali glass with a thickness of 2 mm (Model: No-Alikali Glass 0.4, purchased from: Rocoes), served as a light-transmitting sheet, was preheated at 80° C. for 10 minutes in a batch oven, and the surface temperature thereof was maintained at 50° C. before lamination. For each of the prepared composite films of Examples 1 to 7 and Comparative Examples 1 to 2, the PE protective film thereof was removed, the resulting photosensitive resin film together with PET protective film thereon was placed on the low-alkali glass with the photosensitive resin film facing the low-alkali glass and then pressed with a lamination machine (model: CSL-M25E, purchased from C SUN), wherein a temperature of the lamination machine was 80° C., a pressure of lamination roller was 2.5 kg/cm², and a lamination speed was 2.0 m/min. After the lamination was completed, the resultant laminate was left to stand for 15 minutes, and the PET protective film was removed such that a precursor material of annular support layer is formed on the low-alkali glass.

The low-alkali glass and the precursor material of annular support layer thereon were placed on a heating plate at 80° C. and heated for 5 minutes, and then were cooled at room temperature for 15 minutes to allow them to return to room temperature. The precursor material of annular support layer was exposed by using an exposure machine (model: Contact Aligner, purchased from Deya Optronic), wherein a wavelength of an exposure light source was 365 nm (i line). The exposure was continued until the exposure energy reached 300 mJ/cm². After the exposure was completed, the exposed precursor material of the annular support layer was baked at 70° C. for 5 minutes.

Then, the exposed precursor material of annular support layer was developed under the following conditions such that an annular support layer was formed on the low-alkali glass: propylene glycol methyl ether acetate (PGMEA) was used as a developer, a liquid temperature of 24° C. to 26° C. was set, and an immersion time for performing development was 5 minutes.

The low-alkali glass and the annular support layer were cleaned with pure water and blown dry with nitrogen gas. Then, the low-alkali glass and the annular support layer were placed on a silicon wafer serving as a substrate with the bottom surface of the annular support layer, and the low-alkali glass, the annular support layer and the silicon wafer were heated to 130° C. and pressed at a pressure of 3 kg/cm² for 5 minutes to bond the low-alkali glass and the annular support layer to the silicon wafer. After the bonding was completed, the resultant structure was heated in a batch oven at a temperature of 170° C. for 4 hours, cooled at room temperature for 30 minutes, and then a package structure was obtained.

### 3.3.3. Testing of Annular Support Layer

The properties of the annular support layers of Examples 1 to 7 (E1 to E7) and Comparative Examples 1 and 2 (CE1 and CE2) were tested according to the aforementioned testing methods. The results are tabulated in Table 2 and Table 3.

TABLE 2
Testing results of silicon adhesion and cross-sectional profile of annular support layer

| | E1 | E2 | E3 | E4 | E5 | E6 | E7 | CE1 | CE2 |
|---|---|---|---|---|---|---|---|---|---|
| Height T | 120 | 20 | 60 | 200 | 100 | 100 | 100 | 100 | 60 |
| Width L_{A} | 100 | 400 | 150 | 8 | 200 | 50 | 20 | 100 | 150 |
| T/L_{A} | 1.2 | 0.05 | 0.4 | 25 | 0.5 | 2 | 5 | 1 | 0.4 |
| A₃₅₅/T | 0.0071 | 0.0030 | 0.0145 | 0.0306 | 0.0087 | 0.0097 | 0.0083 | 0.0020 | 0.357 |
| A_{w2}/T | ≤0.0035 | ≤0.0035 | ≤0.0035 | ≤0.0035 | ≤0.0035 | ≤0.0035 | ≤0.0035 | ≤0.0035 | ≤0.0035 |
| \|(L₂ − L₁)\| | <5 | <5 | <5 | <5 | <5 | 5~10 | <5 | >15 | >15 |
| (unit: μm) | | | | | | | | | |
| Cross-sectional | ∘ | ∘ | ∘ | ∘ | ∘ | ∘ | ∘ | x | x |
| shape | | | | | | | | | |
| Footing length | 2 | 1 | 2 | 2 | 2 | 4 | 2 | 30 | 15 |
| (unit: μm) | | | | | | | | | |
| Transmittance | <50% | <50% | <50% | <50% | <50% | <50% | <50% | <50% | >50% |
| TT₅₅₀ | | | | | | | | | |
| Silicon adhesion | 15 | 19 | 18 | 16 | 17 | 14 | 16 | 5 | 3 |
| (unit: kgf/3 mm²) | | | | | | | | | |

TABLE 3
Other properties of annular support layer

| | E1 | E2 | E3 | E4 | E5 | E6 | E7 | CE1 | CE2 |
|---|---|---|---|---|---|---|---|---|---|
| w1 position | 610 | 720 | 615 | 710 | 510 | 605 | 616 | 615 | none |
| (unit: nm) | | | | | | 455 | | | |
| A_{w1}/T | 0.0031 | 0.0193 | 0.0114 | 0.0097 | 0.0049 | 0.0061 | 0.0046 | 0.0058 | — |
| | | | | | | 0.0046 | | | |
| A₄₅₀/T | 0.0020 | 0.0011 | 0.0017 | 0.0020 | 0.0024 | 0.0031 | 0.0022 | 0.0013 | 0.0016 |

As shown in Table 2, Examples 1 to 7 have confirmed that the annular support layers with an absorbance A₃₅₅ at 355 nm that satisfies 0.003≤A₃₅₅/T≤0.03 have good silicon adhesion, good cross-sectional shapes, and short footing lengths, indicating that the annular support layers have excellent cross-sectional profiles. In addition, each of the annular support layers of Examples 1 to 7 has low transmittance at 550 nm, thus providing a package structure with low light transmittance and correspondingly having better anti-glare performance. In contrast, Comparative Examples 1 and 2 show that, if the values of A₃₅₅/T do not satisfy the aforementioned range, the aforementioned good effects cannot be provided.

### 3.4. Comparative Examples 3 to 5

### 3.4.1. Preparation of Photosensitive Resin Film

### Comparative Example 3

The following components were mixed and stirred for 5 hours to be evenly mixed, thereby obtaining a resin composition of Comparative Example 3: 20 parts by weight of BNE200 epoxy resin, 60 parts by weight of BE507 epoxy resin, 20 parts by weight of CNE200ELA epoxy resin, parts by weight of acetone, 4 parts by weight of triphenylsulfonium tetrakis(pentafluorophenyl)borate, 5 parts by weight of KBE-403 silane coupling agent, 0.06 part by weight of Solvent Black, and 15 parts by weight of tetrahydrofuran.

The resin composition of Comparative Example 3 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 3. The conditions of conducting coating and drying are as follows: a coated thickness is 160 m, a drying temperature of 100° C. is applied, a drying duration of 15 minutes is used, and a thickness after drying is 120 m.

### Comparative Example 4

The following components were mixed and stirred for 5 hours to be evenly mixed, thereby obtaining a resin composition of Comparative Example 4: 30 parts by weight of BNE200 epoxy resin, 20 parts by weight of BE507 epoxy resin, 50 parts by weight of PNE177 epoxy resin, 25 parts by weight of acetone, 2 parts by weight of triphenylsulfonium hexafluoroantimonate, 0.3 part by weight of diphenyliodonium tetrakis(pentafluorophenyl)borate, 5 parts by weight of KBE-403 silane coupling agent, 0.05 part by weight of Solvent Blue, and 12 parts by weight of tetrahydrofuran.

The resin composition of Comparative Example 4 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 4. The conditions of conducting coating and drying are as follows: a coated thickness is 160 m, a drying temperature of 100° C. is applied, a drying duration of 20 minutes is used, and a thickness after drying is 120 m.

### Comparative Example 5

The following components were mixed and stirred for 5 hours to be evenly mixed, thereby obtaining a resin composition of Comparative Example 5: 20 parts by weight of BNE200 epoxy resin, 60 parts by weight of BE507 epoxy resin, 20 parts by weight of CNE200ELA epoxy resin, 25 parts by weight of acetone, 2 parts by weight of triphenylsulfonium hexafluoroantimonate, 5 parts by weight of KBE-403 silane coupling agent, 0.2 part by weight of Reactive Yellow, 0.01 part by weight of Solvent Black, and 15 parts by weight of tetrahydrofuran.

The resin composition of Comparative Example 5 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 5. The conditions of conducting coating and drying are as follows: a coated thickness is 140 m, a drying temperature of 95° C. is applied, a drying duration of 20 minutes is used, and a thickness after drying is 100 m.

### 3.4.2. Preparation and Testing of Annular Support Layer and Package Structure

The annular support layers and package structures of Comparative Examples 3 to 5 were prepared in the same manner as Example 1, and then the properties of the annular support layers of Comparative Examples 3 to 5 were measured according to the method described above. As shown in Table 4, if the absorbance of the annular support layer at wavelength w1 does not meet the condition of 0.003≤A_{w1}/T, the cross-sectional profile, silicon adhesion, or light transmittance at 550 nm of the annular support layer is not good.

TABLE 4

| | CE3 | CE4 | CE5 |
|---|---|---|---|
| Height T | 120 | 120 | 100 |
| Width L_{A} | 200 | 150 | 50 |
| T/L_{A} | 0.6 | 0.8 | 2 |
| A₃₅₅/T | 0.0580 | 0.0075 | 0.0064 |
| w1 peak position (nm) | none | 612 | none |
| A_{w1}/T | — | 0.0022 | — |
| A₄₅₀/T | 0.0137 | 0.0027 | 0.0038 |
| A_{w2}/T | >0.0035 | ≤0.0035 | >0.0035 |
| \|(L₂ − L₁)\| (unit: μm) | >15 | >15 | >15 |
| Cross-sectional shape | x | x | x |
| Footing length | 32 | 22 | 18 |
| (unit: μm) | | | |
| Transmittance TT₅₅₀ | <50% | >50% | >50% |
| Silicon adhesion | 4 | 4 | 5 |
| (unit: kgf/3 mm²) | | | |

The above examples are used to illustrate the principle and efficacy of the present invention and show the inventive features thereof, but are not used to limit the scope of the present invention. People skilled in this field may proceed with a variety of modifications and replacements based on the disclosures and suggestions of the invention as described. Therefore, the scope of protection of the present invention is that as defined in the claims as appended.

What is claimed is:

1. A package structure, comprising:
a light-transmitting sheet, having an upper surface and a lower surface;
an annular support layer, disposed on the lower surface of the light-transmitting sheet, and having a top surface facing the light-transmitting sheet, a bottom surface opposite to the top surface, an inner surface, and an outer surface opposite to the inner surface; and
a substrate,
wherein,
the light-transmitting sheet and the annular support layer are disposed on the substrate with the bottom surface of the annular support layer, thereby forming an encapsulation space,
the annular support layer has a height T in m along a direction perpendicular to the light-transmitting sheet, with a corresponding width L_{A} at T/2, the width L_{A} ranging from 8 μm to 400 μm, and 0.05≤T/L_{A}≤25, and
when the annular support layer is characterized by ultraviolet-visible spectroscopy along a direction perpendicular to the top and bottom surfaces of the annular support layer, a resulting spectrum has an absorbance A₃₅₅ at 355 nm, and 0.003<A₃₅₅/T≤0.03.

2. The package structure of claim 1, wherein the ultraviolet-visible spectroscopy is measured by using an ultraviolet-visible spectrophotometer under the following conditions: the annular support layer is placed perpendicularly to a direction of incident light; a diffraction grating is configured as an optical splitter; testing temperature is 25° C.; testing pressure is 1 atm; an analysis mode is absorbance; a range of scanned wavelength is from 190 nm to 1100 nm; a blank sample is air; scan velocity is 2200 nm/min; a switch wavelength at which a light source is switched from a deuterium lamp to a tungsten lamp is 340.8 nm; a sampling interval is 0.2 nm; and a slit width is 2.0 nm.

3. The package structure of claim 1, wherein the annular support layer has a transmittance TT₅₅₀ of not higher than 50% for light with a wavelength of 550 nm, and the transmittance TT₅₅₀ is measured with an incident light direction being perpendicular to the top and bottom surfaces of the annular support layer.

4. The package structure of claim 1, wherein 0.4≤T/L_{A}≤3.

5. The package structure of claim 1, wherein the spectrum has at least one point within a first wavelength ranging from greater than 450 nm to 780 nm where a first derivative equals 0 and a second derivative is less than 0, and the point each independently has an A_{w1}/T value, wherein w1 represents a corresponding wavelength of the point, A_{w1} represents a corresponding absorbance, and 0.003≤A_{w1}/T.

6. The package structure of claim 5, wherein the first wavelength ranges from greater than 480 nm to 730 nm, and an absorbance of the spectrum at each wavelength within a second wavelength range is independently denoted as A_{w2}, with w2 representing wavelength of corresponding absorbance, and wherein 0≤A_{w2}/T≤0.0035, and the second wavelength range is from 440 nm to 470 nm.

7. The package structure of claim 1, wherein the spectrum has an absorbance A₄₅₀ at 450 nm, and 0≤A₄₅₀/T≤0.0035.

8. The package structure of claim 1, wherein the annular support layer has a width L₁ in m at the bottom surface of the annular support layer and a width L₂ in m at the top surface of the annular support layer, and L₁ is not equal to L₂.

9. The package structure of claim 3, wherein the annular support layer has a width L₁ in m at the bottom surface of the annular support layer and a width L₂ in m at the top surface of the annular support layer, and L₁ is not equal to L₂.

10. The package structure of claim 1, wherein the inner surface of the annular support layer is a scattering surface that causes incident light to scatter.

11. The package structure of claim 3, wherein the inner surface of the annular support layer is a scattering surface that causes incident light to scatter.

12. The package structure of claim 1, wherein the light-transmitting sheet is a glass sheet.

13. The package structure of claim 3, wherein the light-transmitting sheet is a glass sheet.

14. The package structure of claim 1, wherein the substrate is a silicon-containing substrate.

15. The package structure of claim 3, wherein the substrate is a silicon-containing substrate.

16. The package structure of claim 1, which further comprises a sensor chip, wherein the sensor chip is electrically connected to the substrate and is located within the encapsulation space.

17. The package structure of claim 3, which further comprises a sensor chip, wherein the sensor chip is electrically connected to the substrate and is located within the encapsulation space.
